(19) United States
(12) Patent Application Publication
(10) Pub. No.: US 2024/0429074 A1
(43) Pub. Date: Dec. 26, 2024

(54) WAFER TEMPERATURE CONTROL DEVICE AND WAFER TEMPERATURE CONTROL METHOD

(71) Applicant: KELK Ltd., Hiratsuka-shi (JP)

(72) Inventors: Kazuhiro Mimura, Hiratsuka-shi (JP); Yuta Kikuchi, Hiratsuka-shi (JP)

(73) Assignee: KELK Ltd., Hiratsuka-shi (JP)

(21) Appl. No.: 18/745,166

(22) Filed: Jun. 17, 2024

(30) Foreign Application Priority Data
Jun. 22, 2023 (JP) 2023-102659
Jun. 22, 2023 (JP) 2023-102660

(51) Int. Cl. H01L 21/67

(52) U.S. Cl. CPC H01L 21/67248

(57) ABSTRACT

A temperature control device for a wafer includes: a mounting unit in which a mounting surface on which a wafer is mountable is partitioned into a plurality of areas; a temperature adjusting unit configured to adjust temperatures of the plurality of areas; temperature sensors configured to detect the temperatures of the plurality of areas; a temperature control unit configured to control the temperatures of the plurality of areas; a disturbance detecting unit configured to detect application of disturbance to the corresponding area; and a switching unit configured to feed only the detected temperature of the temperature sensor provided in the area to which application of disturbance has been detected back to the temperature control unit. The temperature adjusting unit adjusts the temperatures of the plurality of areas on the basis of the detected temperature fed back by the switching unit.

### BACKGROUND OF THE INVENTION

### Field of the Invention

The present disclosure relates to a temperature control device for a wafer and a temperature control method for a wafer.

Priority is claimed on Japanese Patent Application No. 2023-102659 and Japanese Patent Application No. 2023-102660, filed Jun. 22, 2023, the content of which is incorporated herein by reference.

### Description of Related Art

A temperature control device for a wafer prober is disclosed in Patent Document 1. This temperature control device controls the temperature of a wafer at a target temperature and controls an in-plane temperature distribution of the wafer. The temperature control device described in Patent Document 1 includes a stage on which a wafer is mountable and which is partitioned into a plurality of areas in a plan view, a temperature adjusting unit which is provided in each area of the stage and which can independently adjust the temperatures of the areas, and a temperature sensor which is provided in each area of the stage and which detects the temperature of the area. The temperature control device described in Patent Document 1 curbs local heat disturbance and corrects the temperature to a target temperature using the temperature sensor and the temperature adjusting unit provided in an area to which local heat disturbance is applied when local heat disturbance is applied to a chip on the wafer with supply of electric power thereto.

### PATENT DOCUMENTS

[Patent Document 1] Japanese Unexamined Patent Application, First Publication No. 2022-125685

### SUMMARY OF THE INVENTION

In the temperature control device described in Patent Document 1, since it takes time to adjust the temperature to the target temperature after local heat disturbance has been applied to the wafer, it is necessary to more rapidly adjust the temperature of the wafer to the target temperature.

In the temperature control device described in Patent Document 1, when a position to which local heat disturbance is applied changes, the temperature sensor is switched, and overshooting may occur when the detected temperature of the switched temperature sensor is adjusted to a target temperature range through PID control after the temperature sensor has been switched.

The present disclosure has been invented in consideration of the aforementioned circumstances, and an objective thereof is to provide a temperature control device for a wafer and a temperature control method for a wafer that can more rapidly adjust the wafer temperature to a target temperature.

Another objective of the present disclosure is to provide a temperature control device for a wafer and a temperature control method for a wafer that can curb occurrence of overshooting.

According to an aspect of the present disclosure, there is provided a temperature control device for a wafer, including: a mounting unit including a mounting surface on which a wafer is mountable and which is partitioned into a plurality of areas in a plan view; a temperature adjusting unit configured to independently adjust temperatures of the plurality of areas; a plurality of temperature sensors provided in each of the plurality of areas and configured to detect the temperature of the corresponding area; a temperature control unit configured to independently control the temperatures of the plurality of areas using the temperature adjusting unit; a disturbance detecting unit configured to detect application of disturbance to the corresponding area on the basis of a detected temperature from the corresponding temperature sensor; and a switching unit configured to feed only the detected temperature of the temperature sensor provided in the area to which application of disturbance has been detected back to the temperature control unit when application of disturbance has been detected by the disturbance detecting unit, wherein the temperature adjusting unit adjusts the temperatures of the plurality of areas on the basis of the detected temperature fed back by the switching unit.

According to another aspect of the present disclosure, there is provided a temperature control method for a wafer, including: a disturbance detecting step of detecting application of disturbance to a wafer in which a plurality of areas are set in a plan view; and a disturbance-curbed operation step of independently controlling temperatures of all the areas on the basis of a detected temperature of one area to which application of disturbance has been detected in a feedback manner when application of disturbance has been detected.

According to another aspect of the present disclosure, there is provided a temperature control device for a wafer, including: a mounting unit including a mounting surface on which a wafer is mounted; a temperature adjusting unit configured to heat or cool the mounting unit; a plurality of temperature sensors provided in the mounting unit; and a temperature control device configured to control the temperature adjusting unit, wherein the temperature control device includes a plurality of manipulated variable change calculating units provided for each of the plurality of temperature sensors and configured to calculate a manipulated variable change of the temperature adjusting unit on the basis of a detected temperature of the corresponding temperature and a target temperature, a selection and switching unit configured to switch a state in which the manipulated variable change calculated by one of the plurality of manipulated variable change calculating units is selected to a state in which the manipulated variable change calculated by another of the plurality of manipulated variable change calculating units is selected, and a manipulated variable calculating unit configured to calculate the amount of operation of the temperature adjusting unit on the basis of the manipulated variable change selected by the selection and switching unit.

According to another aspect of the present disclosure, there is provided a temperature control method for a wafer, including: a temperature monitoring step of detecting wafer temperatures at a plurality of positions; a manipulated variable change calculating step of calculating the manipulated variable change at each position on the basis of the wafer temperatures at the plurality of positions detected in the temperature monitoring step and a target temperature; a selection and switching step of switching a state in which the manipulated variable change at one position out of the manipulated variable changes at the positions calculated in the manipulated variable change calculating step is selected to a state in which the manipulated variable change at another position is selected; a manipulated variable calculating step of calculating a manipulated variable of the wafer temperature on the basis of the manipulated variable change selected in the selection and switching step; and a temperature adjusting step of adjusting the wafer temperatures on the basis of the manipulated variable calculated in the manipulated variable calculating step.

According to the present disclosure, it is possible to more rapidly adjust a wafer temperature to a target temperature after application of local heat disturbance has stopped. It is also possible to curb occurrence of overshooting.

### BRIEF DESCRIPTION OF THE DRAWINGS

FIG. 1 is a block diagram of a temperature control device.

FIG. 2 is a plan view illustrating an arrangement of temperature detecting units.

FIG. 3 is a sectional view of a mounting unit and the temperature adjusting units.

FIG. 4 is a functional block diagram of a temperature control unit according to a first embodiment.

FIG. 5 is a control block diagram at the time of application of disturbance according to the first embodiment.

FIG. 6 is a control block diagram at the time of normal operation according to the first embodiment.

FIG. 7 is a flowchart of a temperature control method according to the first embodiment.

FIG. 8 is a graph illustrating change in temperature of each area when a normal operation step is switched to a disturbance-curbed operation step according to the first embodiment.

FIG. 9 is a graph illustrating change in temperature corresponding to FIG. 8 according to a comparative example.

FIG. 10 is a graph illustrating change in temperature of each area when a disturbance-curbed operation step is switched to a normal operation step according to the first embodiment.

FIG. 11 is a graph illustrating change in temperature corresponding to FIG. 10 according to a comparative example.

FIG. 12 is a control block diagram of a control device according to a second embodiment.

FIG. 13 is a control block diagram of a manipulated variable change calculating unit according to the second embodiment.

FIG. 14 is a control block diagram of a manipulated variable calculating unit according to the second embodiment.

FIG. 15 is a flowchart of a temperature control method according to the second embodiment.

FIG. 16 is a graph illustrating change in temperature of a main temperature sensor and a secondary temperature sensor and a manipulated variable according to the second embodiment.

FIG. 17 is a control block diagram of a control device according to a comparative example.

### DETAILED DESCRIPTION OF THE INVENTION

Hereinafter, a first embodiment of the present disclosure will be described with reference to the accompanying drawings. In the first embodiment, a temperature control device for controlling a temperature of a wafer (a temperature of a wafer to which heat is locally input with supply of electric power thereto), on which a chip of which electrical characteristics are inspected with supply of electric power thereto is formed, at a target temperature will be described as an example of a temperature control device for a wafer. For example, the wafer is formed in a disk shape.

### <Temperature Control Device>

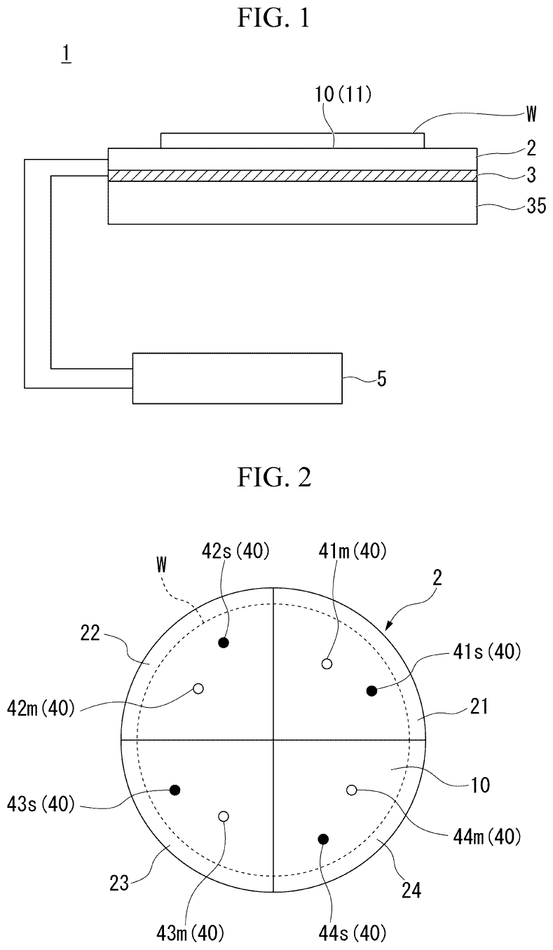

FIG. 1 is a block diagram of a temperature control device 1. FIG. 2 is a plan view illustrating an arrangement of temperature detecting units 4. In FIG. 2, a wafer W is indicated by a dotted line.

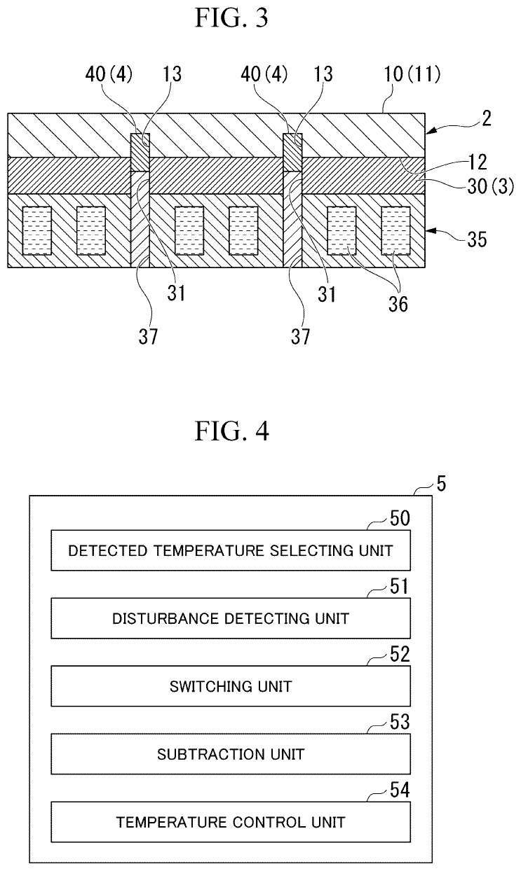

As illustrated in FIG. 1, the temperature control device 1 includes a mounting unit 2, a temperature adjusting unit 3, a temperature detecting unit 4 (see FIG. 3), and a control device 5. Constituents of the temperature control device 1 are controlled by the control device 5.

### <Mounting Unit>

The mounting unit 2 includes a mounting surface 10 on which a wafer W is mountable. The mounting unit 2 is formed in a disk shape including the mounting surface 10 as a first surface 11. As illustrated in FIG. 2, the mounting surface 10 is formed in a circular shape in a plan view. For example, an outer diameter of the mounting surface 10 is equal to or greater than an outer radius of the wafer W. The mounting surface 10 is partitioned into a plurality of (for example, four in the first embodiment) areas 21 to 24 in a plan view. The plurality of areas 21 to 24 are arranged in a circumferential direction of the mounting surface 10 having a circular shape in a plan view. The areas 21 to 24 in the first embodiment have a fan shape formed by equally dividing the mounting surface 10 having a circular shape in a plan view in a circumferential surface. The areas 21 to 24 are arranged in a left-turn (counterclockwise) direction in the order of the areas 21 to 24 in a plan view.

FIG. 3 is a sectional view of the mounting unit and the temperature adjusting unit.

As illustrated in FIG. 3, the mounting unit 2 includes a recessed portion 13 that is open on a second surface 12 opposite to the first surface 11. The recessed portion 13 is not open on the first surface 11 (the mounting surface 10). A plurality of recessed portions 13 are provided in each of the plurality of areas 21 to 24 (see FIG. 2). For example, two recessed portions 13 are provided in each of the areas 21 to 24.

### <Temperature Adjusting Unit>

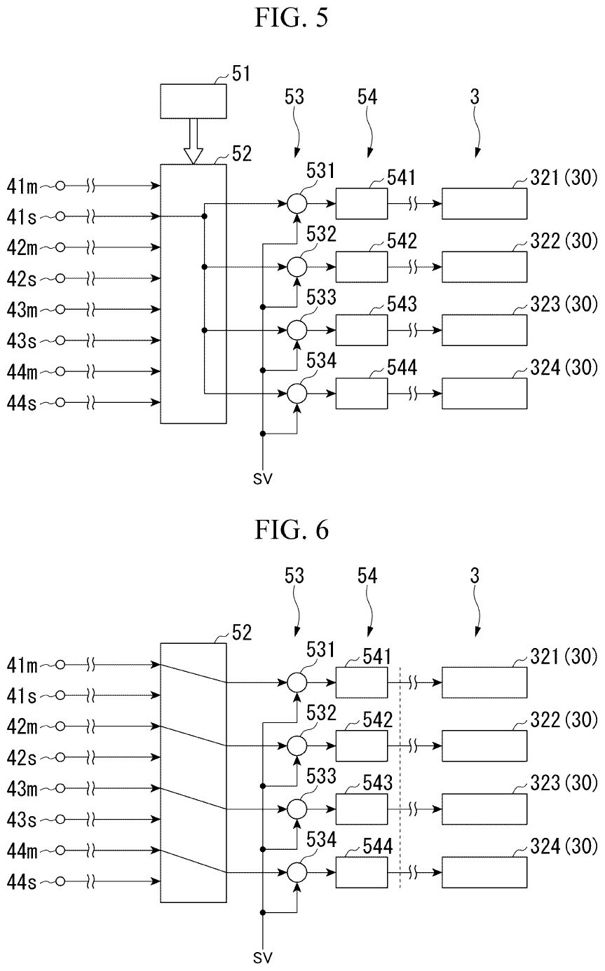

The temperature adjusting unit 3 can heat and cool the mounting unit 2. For example, the temperature adjusting unit 3 independently adjusts the temperature of the mounting unit 2 for each of the plurality of areas 21 to 24. For example, the temperature adjusting unit 3 includes a thermoelectric element 30 such as a Peltier element. For example, the thermoelectric element 30 is provided in each of the plurality of areas 21 to 24. For example, when electric power is supplied to the plurality of thermoelectric elements 30, the plurality of areas 21 to 24 can be independently heated or cooled. The thermoelectric elements 30 of the plurality of areas 21 to 24 are controlled by the control device 5 (see FIG. 1). For example, a thermoelectric element 321 (see FIG. 5) is provided in the area 21, a thermoelectric element 322 (see FIG. 5) is provided in the area 22, a thermoelectric element 323 (see FIG. 5) is provided in the area 23, and a thermoelectric element 324 (see FIG. 5) is provided in the area 24.

The temperature adjusting unit 3 is in contact with the second surface 12 of the mounting unit 2. The temperature adjusting unit 3 includes a through-hole 31 connected to the recessed portion 13. A plurality of through-holes 31 are provided to correspond to the recessed portions 13. For example, two through-holes 31 are provided in each of the plurality of areas 21 to 24.

### <Manipulated Variable Calculating Unit>

The temperature control device 1 according to the first embodiment includes a cooling unit 35 for cooling the temperature adjusting unit 3. For example, the cooling unit 35 is a water-cooled plate and includes a coolant passage 36 in which a coolant can flow. The coolant passage 36 is provided in each of the plurality of areas 21 to 24. The cooling unit 35 can independently cool the areas 21 to 24, for example, by driving a pump which is not illustrated to allow a coolant to flow in the coolant passages 36. For example, pumps corresponding to the coolant passages 36 of the areas 21 to 24 are controlled by the control device 5 (see FIG. 1). The cooling unit 35 includes a penetrating hole 37 connected to the through-hole 31 of the temperature adjusting unit 3. A plurality of penetrating holes 37 are provided to correspond to the through-holes 31. For example, two penetrating holes 37 are provided in each of the plurality of areas 21 to 24.

### <Temperature Detecting Unit>

The temperature detecting unit 4 detects temperatures of the areas 21 to 24 (see FIG. 2). For example, the temperature detecting unit 4 includes a temperature sensor 40 such as a resistance temperature detector (RTD) or a thermocouple (TC). A plurality of temperature sensors 40 are provided in each of the plurality of areas 21 to 24. For example, as illustrated in FIG. 2, two temperature sensors 40 are provided in each of the areas 21 to 24. As illustrated in FIG. 3, each temperature sensor 40 is disposed in the corresponding recessed portion 13 of the mounting unit 2 via the corresponding penetrating hole 37 of the cooling unit 35 and the corresponding through-hole 31 of the temperature adjusting unit 3.

The plurality of temperature sensors 40 are arranged separately from each other in a circumferential direction and a radial direction of the mounting surface 10 in a plan view. The plurality of temperature sensors 40 are arranged separately from each other in each of the plurality of areas 21 to 24 in a plan view. For example, two temperature sensors 40 disposed in each of the areas 21 to 24 are arranged at the same position in the radial direction and arranged at equal intervals in the circumferential direction. A detected temperature from each temperature sensor 40 is input to the control device 5 (see FIG. 1).

For example, two temperature sensors 40 disposed in each of the areas 21 to 24 include a main temperature sensor and a secondary temperature sensor. As illustrated in FIG. 2, for example, a main temperature sensor 41m and a secondary temperature sensor 41s are disposed in the area 21. A main temperature sensor 42m and a secondary temperature sensor 42s are disposed in the area 22. A main temperature sensor 43m and a secondary temperature sensor 43s are disposed in the area 23. A main temperature sensor 44m and a secondary temperature sensor 44s are disposed in the area 24. For example, the main temperature sensors 41m to 44m are arranged at the same position in the areas 21 to 24. The arrangement position of the main temperature sensors 41m to 44m is an optimal position (for example, the center of gravity) for uniformly heating/cooling the areas 21 to 24. For example, the secondary temperature sensors 41s to 44s are arranged at the same position in the areas 21 to 24. The arrangement position of the secondary temperature sensors 41s to 44s is a position at which a range except for the main temperature sensors 41m to 44m in the areas 21 to 24 can be appropriately observed with the given number of sensors.

### <Control Device>

FIG. 4 is a control block diagram of the control device.

The control device 5 controls the temperature adjusting unit 3 on the basis of the detected temperatures from the plurality of temperature sensors 40. For example, the control device 5 controls the temperature adjusting unit 3 through a velocity-type proportional integral derivative (PID) controller to increase the detected temperatures of the temperature sensors 40 to a target temperature SV. As illustrated in FIG. 4, the control device 5 includes a plurality of manipulated variable change calculating units 51, a selection and switching unit 52, and a plurality of manipulated variable calculating units 53.

### <Manipulated Variable Change Calculating Unit>

FIG. 5 is a control block diagram of the manipulated variable change calculating unit.

The manipulated variable change calculating unit 51 is provided for each of the plurality of temperature sensors 40. In the first embodiment, main manipulated variable change calculating units 511m to 514m connected to the main temperature sensors 41m to 44m and secondary manipulated variable change calculating units 511s to 514s connected to the secondary temperature sensor 41s to 44s are provided as the manipulated variable change calculating unit 51. Differences e(k) (wherein “k” indicates a current sampling time) obtained by subtracting the target temperature SV from the detected temperatures from the main temperature sensors 41m to 44m and the secondary temperature sensor 41s to 44s using a subtractor 54 are input to the main manipulated variable change calculating units 511m to 514m and the secondary manipulated variable change calculating units 511s to 514s. As illustrated in FIG. 5, the manipulated variable change calculating unit 51 calculates a current change dP(k) of the P term, a current change dI(k) of the I term, and a current change dD(k) of the D term using a difference e(k) and a difference e(k−1) at a previous sampling time. The manipulated variable change calculating unit 51 calculates a current manipulated variable change ΔMV(k) by adding the change dP(k) of the P term, the change dI(k) of the I term, and the change dD(k) of the D term.

The selection and switching unit 52 can switch a state in which the manipulated variable change ΔMV(k) calculated by one manipulated variable change calculating unit 51 has been selected to a state in which the manipulated variable change ΔMV(k) calculated by another manipulated variable change calculating unit 51 has been selected. As illustrated in FIG. 4, the selection and switching unit 52 according to the first embodiment is configured to switch between the state in which the manipulated variable change ΔMV(k) calculated by the manipulated variable change calculating unit 51 connected to the main temperature sensor has been selected and the state in which the manipulated variable change ΔMV(k) calculated by the manipulated variable change calculating unit 51 connected to the secondary temperature sensor has been selected.

In the first embodiment, for example, the selection and switching unit 52 switches between selection states of two manipulated variable changes ΔMV(k) which are calculation results from the main manipulated variable change calculating unit and the secondary manipulated variable change calculating unit corresponding to the main temperature sensor and the secondary temperature sensor installed in the same area. That is, the selection and switching unit 52 according to the first embodiment selects one of the manipulated variable change ΔMV(k) calculated by the main manipulated variable change calculating unit and the manipulated variable change ΔMV(k) calculated by the secondary manipulated variable change calculating unit. For example, the selection and switching unit 52 according to the first embodiment can individually perform selection and switching for each corresponding area. For example, when a position to which disturbance is applied changes in the same area, the selection and switching unit 52 according to the first embodiment switches the selection state such that the detection result from the temperature sensor 40 closer to the position to which disturbance is applied can be used.

### <Manipulated Variable Calculating Unit>

FIG. 6 is a control block diagram of the manipulated variable calculating unit.

The manipulated variable calculating unit 53 calculates a manipulated variable MV(k) of the temperature adjusting unit 3 on the basis of the manipulated variable change ΔMV(k) selected by the selection and switching unit 52. The manipulated variable calculating unit 53 is provided for each of a plurality of thermoelectric elements 30 provided for each of the areas 21 to 24. For example, in the first embodiment, an manipulated variable calculating unit 531 corresponding to the area 21, a manipulated variable calculating unit 532 corresponding to the area 22, a manipulated variable calculating unit 533 corresponding to the area 23, and a manipulated variable calculating unit 534 corresponding to the area 24 are provided as the plurality of manipulated variable calculating units 53. As illustrated in FIG. 4, a manipulated variable change ΔMV1 is input as the manipulated variable change ΔMV(k) to the manipulated variable calculating unit 531, a manipulated variable change ΔMV2 is input as the manipulated variable change ΔMV(k) to the manipulated variable calculating unit 532, a manipulated variable change ΔMV3 is input as the manipulated variable change ΔMV(k) to the manipulated variable calculating unit 533, and a manipulated variable change ΔMV4 is input as the manipulated variable change ΔMV(k) to the manipulated variable calculating unit 534.

As illustrated in FIG. 6, the manipulated variable calculating unit 53 calculates the current manipulated variable MV(k) by adding the manipulated variable change ΔMV(k) selected by the selection and switching unit 52 to the manipulated variable MV(k−1) at the previous sampling time. As illustrated in FIG. 4, the manipulated variable calculating unit 531 outputs the manipulated variable MV1 as the manipulated variable MV(k) to the thermoelectric element 321, the manipulated variable calculating unit 532 outputs the manipulated variable MV2 to the thermoelectric element 322, the manipulated variable calculating unit 533 outputs the manipulated variable MV3 to the thermoelectric element 323, and the manipulated variable calculating unit 534 outputs the manipulated variable MV4 to the thermoelectric element 324. The manipulated variable calculating unit 53 may include an anti-windup circuit (not illustrated).

### <Temperature Control Method>

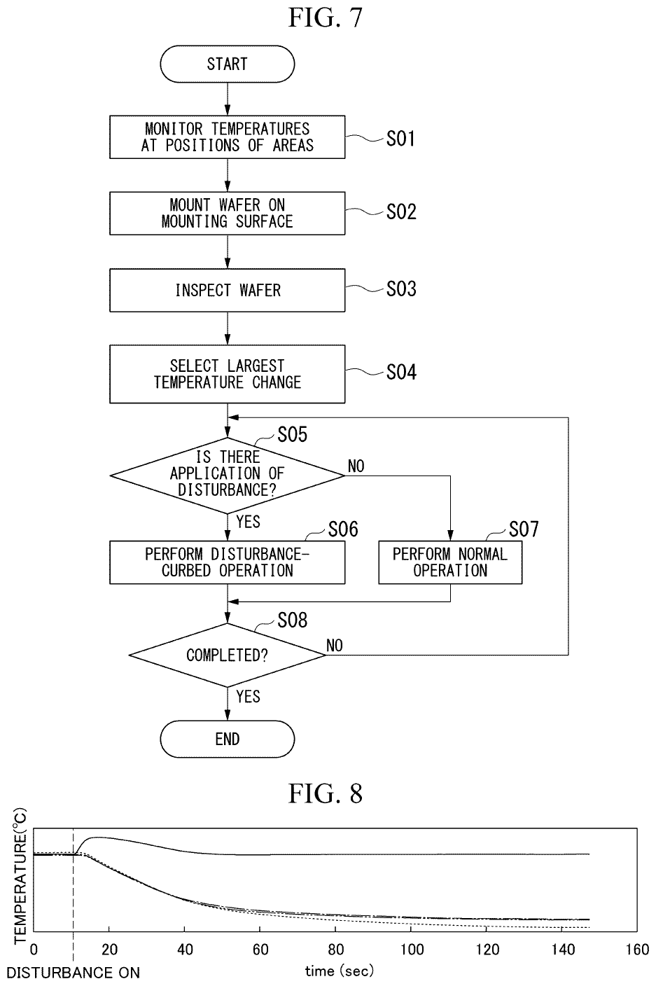

FIG. 7 is a flowchart illustrating a temperature control method according to the first embodiment.

As illustrated in FIG. 7, the temperature control method according to the first embodiment includes a temperature monitoring step S01, a wafer mounting step S02, a wafer inspecting step S03, a manipulated variable change calculating step S04, a selection and switching step S05, a manipulated variable calculating step S06, and a temperature adjusting step S07.

In the temperature monitoring step S01, the temperatures at a plurality of positions in at least one area of the plurality of areas 21 to 24 are monitored. For example, in the temperature monitoring step S01, the temperatures at a plurality of positions in each of the plurality of areas 21 to 24 are monitored. For example, in the temperature monitoring step S01, all of the plurality of temperature sensors 40 provided in each of the plurality of areas 21 to 24 are normally monitored. After the temperature monitoring step S01, the process flow transitions to the wafer mounting step S02.

In the wafer mounting step S02, a wafer W is mounted on the mounting surface 10 including the plurality of areas 21 to 24. For example, in the wafer mounting step S02, a disc-shaped wafer W is mounted to overlap the mounting surface 10 having a circular shape in a plan view as a whole. After the wafer mounting step S02, the process flow transitions to the wafer inspecting step S03.

In the wafer inspecting step S03, inspection of the wafer W mounted on the mounting surface 10 is started. For example, local heat input occurs as application of disturbance through the inspection of the wafer W. After the wafer inspecting step S03 has been started, the process flow transitions to the manipulated variable change calculating step S04.

In the manipulated variable change calculating step S04, the manipulated variable change ΔMV(k) at each position is calculated on the basis of the detected temperature (a wafer temperature) at the plurality of positions detected in the temperature monitoring step S01 and a target temperature SV. For example, in the first embodiment, the manipulated variable change ΔMV(k) is calculated by causing the manipulated variable change calculating unit 51 to add the change dP(k) of the P term, the change dI(k) of the I term, and the change dD(k) of the D term.

In the selection and switching step S05, a state in which the manipulated variable change at one position out of the manipulated variable changes at the positions calculated in the manipulated variable change calculating step S04 has been selected is switched to a state in which the manipulated variable change at another position has been selected. In the first embodiment, as described above, a state in which one of two manipulated variable changes ΔMV(k) calculated on the basis of the detected temperatures of the main temperature sensor and the secondary temperature sensor installed in the same area has been selected is set. The state in which one of two manipulated variable changes ΔMV(k) has been selected is switched to the state in which the other has been selected according to necessity. For example, in the selection and switching step S05 according to the first embodiment, selection and switching of the manipulated variable change ΔMV(k) is performed for each of the areas 21 to 24.

In the manipulated variable calculating step S06, the manipulated variable MV(k) used to adjust the temperature is calculated on the basis of the manipulated variable change ΔMV(k) selected in the selection and switching step S05. For example, in the first embodiment, the current manipulated variable MV(k) is calculated by causing the manipulated variable calculating unit 53 to add the manipulated variable change ΔMV(k) to the manipulated variable MV(k−1) at the previous sampling time.

In the temperature adjusting step S07, the wafer temperature is adjusted on the basis of the manipulated variable MV(k) calculated in the manipulated variable calculating step S06. That is, the wafer W is heated or cooled using the thermoelectric element 30 in the area corresponding to the manipulated variable MV on the basis of the calculated manipulated variable MV.

FIG. 8 is a graph illustrating temperature changes and manipulated variable of the main temperature sensor and the secondary temperature sensor according to the first embodiment. In FIG. 8, the temperature change and the manipulated variable according to the first embodiment are indicated by a solid line, and a temperature change and a manipulated variable in a comparative example are indicated by a lines (a dotted line, an alternated long and short dash line, and an alternated long and two short dashes line) other than a solid line. In FIG. 8, it is assumed that the temperature sensor 40 for controlling the temperature of the area 21 in a feedback manner is switched from the main temperature sensor 41m to the secondary temperature sensor 41s. It is also assumed that the detected temperature of the main temperature sensor 41m is higher than the detected temperature of the second temperature sensor 41s.

As illustrated in FIG. 8, in a state in which the detected temperature of the main temperature sensor 41m has been corrected to the target temperature SV, the main temperature sensor 41m is switched to the secondary temperature sensor 41s (a “sensor switching” time point in FIG. 8). The state in which the manipulated variable change ΔMV(k) calculated by the main manipulated variable change calculating unit 511m has been selected is switched to the state in which the manipulated variable change ΔMV(k) calculated by the secondary manipulated variable change calculating unit 511s has been selected by the selection and switching unit 52. At this time, the manipulated variable MV1 output from the manipulated variable calculating unit 531 according to the first embodiment is calculated through the velocity-type PID control and thus increases gradually with the elapse of time, a rate of increase thereof decreases with the elapse of time, and the manipulated variable MV1 reaches a predetermined peak value. Thereafter, the manipulated variable MV1 decreases gradually with the elapse of time, a rate of decrease decreases gradually, and the manipulated variable MV1 reaches the same constant manipulated variable MV as before the sensor switching time point. When the thermoelectric element 321 is controlled on the basis of the manipulated variable MV1, the detected temperature of the secondary temperature sensor 41s increases gradually from the sensor switching time point and is adjusted without exceeding the target temperature SV.

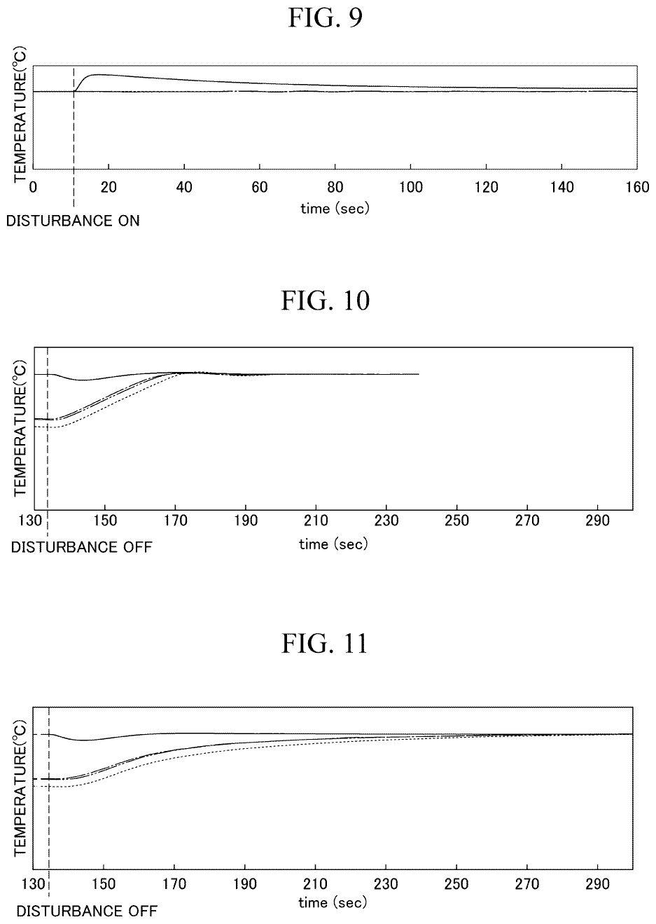

FIG. 9 is a control block diagram of a control device according to a comparative example. The same elements in the comparative example as in the first embodiment will be referred to by the same reference signs.

The temperature control device according to the comparative example includes a mount unit 2 (see FIG. 3), a temperature adjusting unit 3 (see FIG. 3), a temperature detecting unit 4 (see FIG. 3), and a control device 105 (see FIG. 9). In the temperature control device according to the comparative example, similarly to the first embodiment, the mounting surface 10 (see FIG. 2) is partitioned into four areas 21 to 24, and one main temperature sensor and one secondary temperature sensor constituting the temperature detecting unit 4 are provided in each area. That is, the main temperature sensor 41m and the secondary temperature sensor 41s are provided in the area 21, the main temperature sensor 42m and the secondary temperature sensor 42s are provided in the area 22, the main temperature sensor 43m and the secondary temperature sensor 43s are provided in the area 23, and the main temperature sensor 44m and the secondary temperature sensor 44s are provided in the area 24.

The control device 105 controls the temperature adjusting unit 3 (the thermoelectric elements 30) on the basis of the detected temperatures of the plurality of temperature sensors 40. For example, the control device 105 controls the detected temperatures of the temperature sensors 40 to reach the target temperature SV through PID control. As illustrated in FIG. 9, the control device 105 includes a selection and switching unit 152, a subtractor 54, and manipulated variable calculating units 153 to 156. The selection and switching unit 152 can select the detected temperature of one temperature sensor by switching between the main temperature sensor and the secondary temperature sensor for each area. The detected temperatures selected by the selection and switching unit 152 are input to the corresponding manipulated variable calculating units 153 to 156 via the subtractor 54 for each area. The manipulated variable calculating units 153 to 156 calculate manipulated variable MV1 to MV4 of the temperature adjusting unit 3 through the PID control on the basis of the inputs from the subtractors 54.

As illustrated in FIG. 8, in the comparative example employing the aforementioned configuration, for example, when the main temperature sensor 41m is switched to the secondary temperature sensor 41s by the selection and switching unit 152, a so-called switching shock occurs. Specifically, the manipulated variable MV1 (which is indicated by the dotted line in FIG. 8) of the thermoelectric element 321 increases almost vertically at the sensor switching time point and decreases quickly to equal to or lower than the manipulated variable MV at a time point before the sensor switching time point when the manipulated variable MV1 reaches a peak value (for example, equal to or greater than two times MV1) higher than the peak of the manipulated variable MV1, and the manipulated variable becomes the constant manipulated variable MV1 at a time point before the sensor switching time point. When the thermoelectric element 321 is controlled using the manipulated variable MV according to the comparative example, the detected temperature (which is indicated by the alternated long and short dash line in FIG. 8) of the secondary temperature sensor 41s increases quickly at the sensor switching time point, exceeds (overshoots) the target temperature SV, and then is adjusted to the target temperature SV.

### Operations and Advantages

As described above, the temperature control device 1 for a wafer according to the first embodiment includes the mounting unit 2 including the mounting surface 10 on which a wafer W is mountable, the temperature adjusting unit 3 configured to heat and cool the mounting unit 2, a plurality of temperature sensors 40 provided in the mounting unit 2, and the control device 5 configured to control the temperature adjusting unit 3. The control device 5 includes a plurality of manipulated variable change calculating units 51 provided for the plurality of temperature sensors 40 and configured to calculate a manipulated variable change ΔMV(k) of the temperature adjusting unit 3 on the basis of the detected temperature of the corresponding temperature sensor 40 and the target temperature SV, the selection and switching unit 52 configured to switch a state in which the manipulated variable change ΔMV(k) calculated by one manipulated variable change calculating unit 51 has been selected to a state in which the manipulated variable change ΔMV(k) calculated by the other manipulated variable change calculating unit 51 has been selected, and the manipulated variable calculating unit 53 configured to calculate a manipulated variable MV(k) of the temperature adjusting unit 3 on the basis of the manipulated variable change ΔMV(k) selected by the selection and switching unit 52.

According to this configuration, when the state in which the manipulated variable change ΔMV(k) calculated by one manipulated variable change calculating unit 51 has been selected is switched to the state in which the manipulated variable change ΔMV(k) calculated by another manipulated variable change calculating unit 51 has been selected, it is possible to decrease a change of the manipulated variable MV(k) at the time of switching in comparison with a case in which the manipulated variable MV(k) is switched. Accordingly, without extending the time until the temperature of the wafer W is adjusted to the target temperature SV, it is possible to curb overshooting of the wafer temperature with respect to the target temperature SV.

In the first embodiment, the plurality of temperature sensors 40 include the main temperature sensors 41m to 44m and the secondary temperature sensors 41s and 44s, and the plurality of manipulated variable change calculating units 51 include the main manipulated variable change calculating units 511m to 514m configured to calculate the manipulated variable change ΔMV(k) of the temperature adjusting unit 3 on the basis of the detected temperatures of the main temperature sensors 41m to 44m and the target temperature SV and the secondary manipulated variable change calculating units 511s to 514s configured to calculate the manipulated variable change ΔMV(k) of the temperature adjusting unit 3 on the basis of the detected temperatures of the secondary temperature sensors 41s to 44s and the target temperature SV. The selection and switching unit 52 selects one of the manipulated variable change ΔMV(k) calculated by the main manipulated variable change calculating units 511m to 514m and the manipulated variable change ΔMV(k) calculated by the secondary manipulated variable change calculating units 511s to 514s.

Accordingly, when temperature control based on the main temperature sensor and temperature control based on the secondary temperature sensor are switched to each other, a change of a manipulated variable MV(k) can be decreased, and thus it is possible to curb overshooting of the wafer temperature with respect to the target temperature SV.

In the first embodiment, the mounting surface 10 is partitioned into a plurality of areas 21 to 24 in a plan view, and the thermoelectric elements 30 of the temperature adjusting unit 3, the main temperature sensors 41m to 44m, and the secondary temperature sensors 41s to 44s are provided in the corresponding areas 21 to 24. The manipulated variable calculating unit 53 is provided for each of a plurality of thermoelectric elements 321 to 324 of the temperature adjusting unit 3, the main manipulated variable change calculating units 511m to 514m are provided for the corresponding main temperature sensors 41m to 44m, and the secondary manipulated variable change calculating units 511s to 514s are provided for the corresponding secondary temperature sensors 41s to 44s. The selection and switching unit 52 selects one of the manipulated variable change ΔMV(k) calculated by the main manipulated variable change calculating units 511m to 514m and the manipulated variable change ΔMV(k) calculated by the secondary manipulated variable change calculating units 511s to 514s and outputs the selected one to the manipulated variable calculating units 531 to 534 for each of the plurality of areas 21 to 24.

With this configuration, since it is not necessary to provide the same number of manipulated variable calculating units 531 to 534 as the number of temperature sensors 40 or the number of manipulated variable change calculating units 51, it is possible to simplify the circuit configuration of the control device 5.

In the first embodiment, the control device 5 performs the velocity-type PID control using the manipulated variable change calculating units 51 and the manipulated variable calculating units 53.

Accordingly, it is possible to quickly adjust the temperature of the wafer W to the target temperature SV while decreasing the difference between the temperature of the wafer W and the target temperature SV.

The temperature control method for a wafer according to the first embodiment includes: the temperature monitoring step S01 of detecting wafer temperatures at a plurality of positions; the manipulated variable change calculating step S04 of calculating the manipulated variable change ΔMV(k) at each position on the basis of the wafer temperatures at the plurality of positions detected in the temperature monitoring step S01 and a target temperature SV; the selection and switching step S05 of switching a state in which the manipulated variable change ΔMV(k) at one position out of the manipulated variable changes ΔMV(k) at the positions calculated in the manipulated variable change calculating step S04 is selected to a state in which the manipulated variable change ΔMV(k) at another position is selected; the manipulated variable calculating step S06 of calculating a manipulated variable MV(k) by which a temperature is adjusted on the basis of the manipulated variable change ΔMV(k) selected in the selection and switching step S05; and the temperature adjusting step S07 of adjusting the temperature of the wafer W on the basis of the manipulated variable MV(k) calculated in the manipulated variable calculating step S06.

With this configuration, it is possible to decrease a change of the manipulated variable MV(k) at the time of switching in comparison with a case in which the manipulated variable MV(k) is switched. Accordingly, without extending the time until the temperature of the wafer W is adjusted to the target temperature SV, it is possible to curb overshooting of the wafer temperature with respect to the target temperature SV.

### Modified Examples of First Embodiment

In the first embodiment, an example in which the mounting surface is formed in a circular shape in a plan view has been described above, but the present disclosure is not limited thereto. For example, the mounting surface may be formed in a rectangular shape in a plan view. For example, the shape of the mounting surface in a plan view may be changed according to required specifications such as the shape of the wafer W.

In the first embodiment, an example in which a plurality of temperature sensors 40 are arranged separately from each other in the circumferential direction and the radial direction of the mounting surface in a plan view has been described above, but the present disclosure is not limited thereto. For example, the plurality of temperature sensors 40 may not be arranged separately from each other in the circumferential direction and the radial direction of the mounting surface in a plan view. For example, the arrangement form of the plurality of temperature sensors 40 may be changed according to required specifications.

In the first embodiment, an example in which four areas 21 to 24 with a fan shape are arranged in the circumferential directions has been described above, but the present disclosure is not limited thereto. For example, the shape and the arrangement form of the areas may be changed according to required specifications.

In the first embodiment, an example in which a plurality of sensors 40 are provided in each of the plurality of areas 21 to 24 has been described above, but the present disclosure is not limited thereto. For example, the installation number and the installation positions of the temperature sensors 40 may be changed according to required specifications.

In the first embodiment, an example in which the control device 5 monitors the detected temperatures of the plurality of temperature sensors 40 provided in a predetermined area and selects the detected temperature with a largest change in temperature per unit time out of the plurality of monitored detected temperatures has been described above, but the present disclosure is not limited thereto.

In the first embodiment, an example in which the mounting unit 2 is formed in a plate shape including the mounting surface 10 as the first surface 11 has been described above, but the present disclosure is not limited thereto. For example, the mounting unit 2 may be formed in a block shape including the mounting surface 10 as the first surface 11. For example, the shape of the mounting unit 2 may be changed according to required specifications.

In the first embodiment, an example in which the temperature adjusting unit 3 is provided on the second surface 12 opposite to the surface of the mounting unit 2 on which the mounting surface 10 is provided has been described above, but the present invention is not limited thereto. For example, the temperature adjusting unit 3 may be incorporated into the mounting unit 2. For example, the installation form of the temperature adjusting unit 3 may be changed according to required specifications.

In the first embodiment, an example in which the temperature sensors 40 are disposed in the recessed portions 13 of the mounting unit 2 via the through-holes 31 of the temperature adjusting unit 3 and detect the temperatures of the corresponding areas via the recessed portions 13 of the mounting unit 2 has been described above, but the present disclosure is not limited thereto. For example, the temperature sensors 40 may detect the temperatures of the corresponding areas without using the recessed portions 13 of the mounting unit 2. For example, each temperature sensor 40 may be a non-contact temperature sensor. For example, the form of the temperature sensors 40 may be changed according to required specifications.

In the first embodiment, the temperature control device 1 for controlling the temperature of the wafer W (the temperature of the wafer W to which heat is locally input with supply of electric power) including a chip of which electrical characteristics are inspected with supply of electric power in a target temperature SV has been described as an example of the temperature control device for a wafer, but the present disclosure is not limited thereto. For example, the temperature control device 1 may be applied to a temperature control device for controlling the temperature of the wafer W not including a chip of which electrical characteristics are inspected with supply of electric power in a target temperature SV. For example, the temperature control device 1 may be applied to a temperature control device for controlling the temperature of the wafer W such as a silicon wafer in a target temperature SV. For example, the temperature control device 1 may be used in a dry process. For example, the use form of the temperature control device may be changed according to required specifications.

In the first embodiment, the velocity-type PID control is performed, but the present disclosure is not limited thereto. For example, PD (proportional derivative) control may be performed instead of the PID (proportional integral derivative) control.

While the first embodiment of the present disclosure has been described above, the present disclosure is not limited to the first embodiment, addition, omission, substitution without departing from the gist of the present disclosure, and other modification of constituents can be performed thereon, and the first embodiment can also be appropriately combined.

### Second Embodiment

A second embodiment of the present disclosure will be described below with reference to the accompanying drawings. Above description with reference to FIGS. 1 to 3 will be used for the second embodiment, the same constituents as in the first embodiment will be referred to by the same reference signs, and repeated description thereof will be omitted.

### <Temperature Control Device>

As illustrated in FIG. 1, the temperature control device 1 includes the mounting unit 2, the temperature adjusting unit 3, the temperature detecting unit 4 (see FIG. 3), and the control device 5. The constituents of the temperature control device 1 are controlled by the control device 5.

### <Temperature Adjusting Unit>

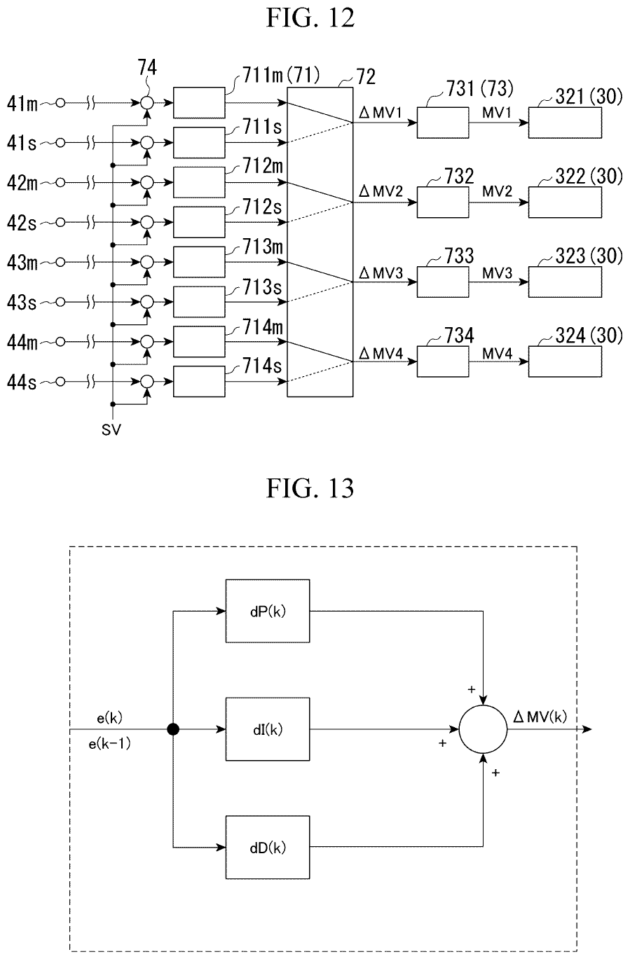

The temperature adjusting unit 3 can heat and cool the mounting unit 2. For example, the temperature adjusting unit 3 independently adjusts the temperature of the mounting unit 2 for each of a plurality of areas 21 to 24. For example, the temperature adjusting unit 3 includes a thermoelectric element 30 such as a Peltier element. For example, the thermoelectric element 30 is provided in each of the plurality of areas 21 to 24. For example, when electric power is supplied to the plurality of thermoelectric elements 30, it is possible to independently heat and cool the areas 21 to 24. The thermoelectric element 30 in each of the areas 21 to 24 is controlled by the control device 5 (see FIG. 1). For example, the thermoelectric element 321 (see FIG. 12) is provided in the area 21, the thermoelectric element 322 (see FIG. 12) is provided in the area 22, the thermoelectric element 323 (see FIG. 12) is provided in the area 23, and the thermoelectric element 324 (see FIG. 12) is provided in the area 24.

### <Control Device>

FIG. 12 is a control block diagram of the control device according to the second embodiment.

The control device 5 controls the temperature adjusting unit 3 on the basis of detected temperatures of a plurality of temperature sensors 40. For example, the control device 5 controls the temperature adjusting unit 3 through velocity-type PID control such that the detected temperatures of the temperature sensors 40 are adjusted to a target temperature SV. As illustrated in FIG. 12, the control device 5 includes a plurality of manipulated variable change calculating units 71, a selection and switching unit 72, and a plurality of manipulated variable calculating units 73.

### <Manipulated Variable Change Calculating Unit>

FIG. 13 is a control block diagram of the manipulated variable change calculating unit according to the second embodiment.

The manipulated variable change calculating unit 71 is provided for each of the plurality of temperature sensors 40. In this embodiment, main manipulated variable change calculating units 711m to 714m connected to the main temperature sensors 41m to 44m and secondary manipulated variable change calculating units 711s to 714s connected to the secondary temperature sensors 41s to 44s are provided as the manipulated variable change calculating units 71. Differences e(k) (where “k” indicates a current sampling time) obtained by subtracting the target temperature SV from the detected temperatures of the main temperature sensors 41m to 44m and the secondary temperature sensor 41s to 44s using a subtractor 74 are input to the main manipulated variable change calculating units 711m to 714m and the secondary manipulated variable change calculating units 711s to 714s. As illustrated in FIG. 13, the manipulated variable change calculating unit 71 calculates a current change dP(k) of the P term, a current change dI(k) of the I term, and a current change dD(k) of the D term using the difference e(k) and the difference e(k−1) at a previous sampling time. The manipulated variable change calculating unit 71 calculates a current manipulated variable change ΔMV(k) by adding the change dP(k) of the P term, the change dI(k) of the I term, and the change dD(k) of the D term.

The selection and switching unit 72 can switch a state in which the manipulated variable change ΔMV(k) calculated by one manipulated variable change calculating unit 71 has been selected to a state in which the manipulated variable change ΔMV(k) calculated by another manipulated variable change calculating unit 71 has been selected. As illustrated in FIG. 12, the selection and switching unit 72 according to this embodiment is configured to switch between the state in which the manipulated variable change ΔMV(k) calculated by the manipulated variable change calculating unit 71 connected to the main temperature sensor has been selected and the state in which the manipulated variable change ΔMV(k) calculated by the manipulated variable change calculating unit 71 connected to the secondary temperature sensor has been selected.

In the second embodiment, for example, the selection and switching unit 72 switches between selection states of two manipulated variable changes ΔMV(k) which are calculation results from the main manipulated variable change calculating unit and the secondary manipulated variable change calculating unit corresponding to the main temperature sensor and the secondary temperature sensor installed in the same area. That is, the selection and switching unit 72 according to this embodiment selects one of the manipulated variable change ΔMV(k) calculated by the main manipulated variable change calculating unit and the manipulated variable change ΔMV(k) calculated by the secondary manipulated variable change calculating unit. For example, the selection and switching unit 72 according to this embodiment can individually perform selection and switching for each corresponding area. For example, when a position to which disturbance is applied changes in the same area, the selection and switching unit 72 according to this embodiment switches the selection state such that the detection result from the temperature sensor 40 closer to the position to which disturbance is applied can be used.

### <Manipulated Variable Calculating Unit>

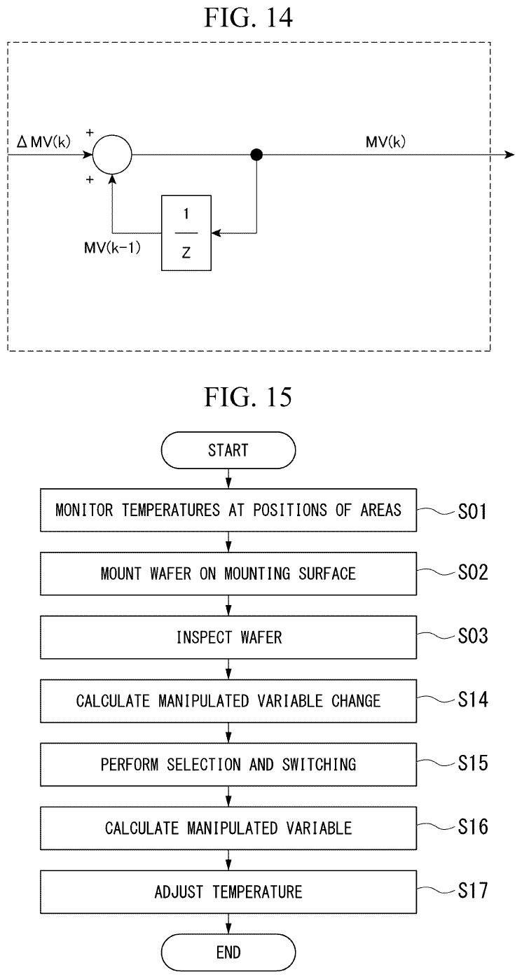

FIG. 14 is a control block diagram of the manipulated variable calculating unit according to the second embodiment.

The manipulated variable calculating unit 73 calculates a manipulated variable MV(k) of the temperature adjusting unit 3 on the basis of the manipulated variable change ΔMV(k) selected by the selection and switching unit 72. The manipulated variable calculating unit 73 is provided for each of a plurality of thermoelectric elements 30 provided for each of the areas 21 to 24. For example, in this embodiment, a manipulated variable calculating unit 731 corresponding to the area 21, a manipulated variable calculating unit 732 corresponding to the area 22, a manipulated variable calculating unit 733 corresponding to the area 23, and a manipulated variable calculating unit 734 corresponding to the area 24 are provided as the plurality of manipulated variable calculating units 73. As illustrated in FIG. 12, a manipulated variable change ΔMV1 is input as the manipulated variable change ΔMV(k) to the manipulated variable calculating unit 731, a manipulated variable change ΔMV2 is input as the manipulated variable change ΔMV(k) to the manipulated variable calculating unit 732, a manipulated variable change ΔMV3 is input as the manipulated variable change ΔMV(k) to the manipulated variable calculating unit 733, and a manipulated variable change ΔMV4 is input as the manipulated variable change ΔMV(k) to the manipulated variable calculating unit 734.

As illustrated in FIG. 14, the manipulated variable calculating unit 73 calculates the current manipulated variable MV(k) by adding the manipulated variable change ΔMV(k) selected by the selection and switching unit 72 to the manipulated variable MV(k−1) at the previous sampling time. As illustrated in FIG. 14, the manipulated variable calculating unit 731 outputs the manipulated variable MV1 as the manipulated variable MV(k) to the thermoelectric element 321, the manipulated variable calculating unit 732 outputs the manipulated variable MV2 to the thermoelectric element 322, the manipulated variable calculating unit 733 outputs the manipulated variable MV3 to the thermoelectric element 323, and the manipulated variable calculating unit 734 outputs the manipulated variable MV4 to the thermoelectric element 324. The manipulated variable calculating unit 73 may include an anti-windup circuit (not illustrated).

### <Temperature Control Method>

FIG. 15 is a flowchart illustrating a temperature control method according to the second embodiment.

As illustrated in FIG. 15, the temperature control method according to the embodiment includes a temperature monitoring step S01, a wafer mounting step S02, a wafer inspecting step S03, a manipulated variable change calculating step S14, a selection and switching step S15, a manipulated variable calculating step S16, and a temperature adjusting step S17.

In the temperature monitoring step S01, the temperatures at a plurality of positions in at least one area of the plurality of areas 21 to 24 are monitored. For example, in the temperature monitoring step S01, the temperatures at a plurality of positions in each of the plurality of areas 21 to 24 are monitored. For example, in the temperature monitoring step S01, all of the plurality of temperature sensors 40 provided in each of the plurality of areas 21 to 24 are normally monitored. After the temperature monitoring step S01, the process flow transitions to the wafer mounting step S02.

In the wafer mounting step S02, a wafer W is mounted on the mounting surface 10 including the plurality of areas 21 to 24. For example, in the wafer mounting step S02, a disc-shaped wafer W is mounted to overlap the mounting surface 10 having a circular shape in a plan view as a whole. After the wafer mounting step S02, the process flow transitions to the wafer inspecting step S03.

In the wafer inspecting step S03, inspection of the wafer W mounted on the mounting surface 10 is started. For example, local heat input occurs as application of disturbance through the inspection of the wafer W. After the wafer inspecting step S03 has been started, the process flow transitions to the manipulated variable change calculating step S14.

In the manipulated variable change calculating step S14, the manipulated variable change ΔMV(k) at each position is calculated on the basis of the detected temperature (a wafer temperature) at the plurality of positions detected in the temperature monitoring step S01 and a target temperature SV. For example, in this embodiment, the manipulated variable change ΔMV(k) is calculated by causing the manipulated variable change calculating unit 71 to add the change dP(k) of the P term, the change dI(k) of the I term, and the change dD(k) of the D term.

In the selection and switching step S15, a state in which the manipulated variable change at one position out of the manipulated variable changes at the positions calculated in the manipulated variable change calculating step S14 has been selected is switched to a state in which the manipulated variable change at another position has been selected. In this embodiment, as described above, a state in which one of two manipulated variable changes ΔMV(k) calculated on the basis of the detected temperatures of the main temperature sensor and the secondary temperature sensor installed in the same area has been selected is set. The state in which one of two manipulated variable changes ΔMV(k) has been selected is switched to the state in which the other has been selected according to necessity. For example, in the selection and switching step S15 according to this embodiment, selection and switching of the manipulated variable change ΔMV(k) is performed for each of the areas 21 to 24.

In the manipulated variable calculating step S16, the manipulated variable MV(k) used to adjust the temperature is calculated on the basis of the manipulated variable change ΔMV(k) selected in the selection and switching step S15. For example, in this embodiment, the current manipulated variable MV(k) is calculated by causing the manipulated variable calculating unit 73 to add the manipulated variable change ΔMV(k) to the manipulated variable MV(k−1) at the previous sampling time.

In the temperature adjusting step S17, the wafer temperature is adjusted on the basis of the manipulated variable MV(k) calculated in the manipulated variable calculating step S16. That is, the wafer W is heated or cooled using the thermoelectric element 30 in the area corresponding to the manipulated variable MV on the basis of the calculated manipulated variable MV.

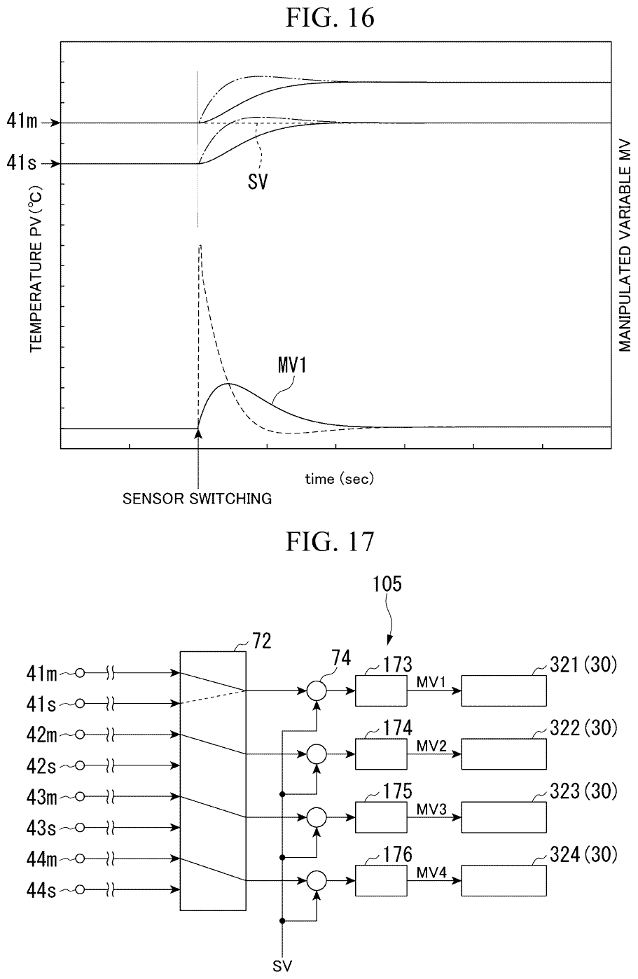

FIG. 16 is a graph illustrating temperature changes and manipulated variable of the main temperature sensor and the secondary temperature sensor according to the second embodiment. In FIG. 16, the temperature change and the manipulated variable according to the second embodiment are indicated by a solid line, and a temperature change and an manipulated variable in a comparative example are indicated by lines (a dotted line, an alternated long and short dash line, and an alternated long and two short dashes line) other than a solid line. In FIG. 16, it is assumed that the temperature sensor 40 for controlling the temperature of the area 21 in a feedback manner is switched from the main temperature sensor 41m to the secondary temperature sensor 41s. It is also assumed that the detected temperature of the main temperature sensor 41m is higher than the detected temperature of the second temperature sensor 41s.

As illustrated in FIG. 16, in a state in which the detected temperature of the main temperature sensor 41m has been adjusted to the target temperature SV, the main temperature sensor 41m is switched to the secondary temperature sensor 41s (a “sensor switching” time point in FIG. 16). The state in which the manipulated variable change ΔMV(k) calculated by the main manipulated variable change calculating unit 711m has been selected is switched to the state in which the manipulated variable change ΔMV(k) calculated by the secondary manipulated variable change calculating unit 711s has been selected by the selection and switching unit 72. At this time, the manipulated variable MV1 output from the manipulated variable calculating unit 731 according to the embodiment is calculated through the velocity-type PID control and thus increases gradually with the elapse of time, a rate of increase thereof decreases with the elapse of time, and the manipulated variable MV1 reaches a predetermined peak value. Thereafter, the manipulated variable MV1 decreases gradually with the elapse of time, a rate of decrease decreases gradually, and the manipulated variable MV1 reaches the same constant manipulated variable MV as before the sensor switching time point. When the thermoelectric element 321 is controlled on the basis of the manipulated variable MV1, the detected temperature of the secondary temperature sensor 41s increases gradually from the sensor switching time point and is adjusted without exceeding the target temperature SV.

FIG. 17 is a control block diagram of a control device according to a comparative example. The same elements in the comparative example as in the embodiment will be referred to by the same reference signs.

The temperature control device according to the comparative example includes a mount unit 2 (see FIG. 3), a temperature adjusting unit 3 (see FIG. 3), a temperature detecting unit 4 (see FIG. 3), and a control device 105 (see FIG. 17). In the temperature control device according to the comparative example, similarly to the second embodiment, the mounting surface 10 (see FIG. 2) is partitioned into four areas 21 to 24, and one main temperature sensor and one secondary temperature sensor constituting the temperature detecting unit 4 are provided in each area. That is, the main temperature sensor 41m and the secondary temperature sensor 41s are provided in the area 21, the main temperature sensor 42m and the secondary temperature sensor 42s are provided in the area 22, the main temperature sensor 43m and the secondary temperature sensor 43s are provided in the area 23, and the main temperature sensor 44m and the secondary temperature sensor 44s are provided in the area 24.

The control device 105 controls the temperature adjusting unit 3 (the thermoelectric elements 30) on the basis of the detected temperatures of the plurality of temperature sensors 40. For example, the control device 105 controls the detected temperatures of the temperature sensors 40 to reach the target temperature SV through PID control. As illustrated in FIG. 17, the control device 105 includes a selection and switching unit 172, a subtractor 74, and manipulated variable calculating units 173 to 176. The selection and switching unit 172 can select the detected temperature of one temperature sensor by switching between the main temperature sensor and the secondary temperature sensor for each area. The detected temperatures selected by the selection and switching unit 172 are input to the corresponding manipulated variable calculating units 173 to 176 via the subtractor 74 for each area. The manipulated variable calculating units 173 to 176 calculate manipulated variable MV1 to MV4 of the temperature adjusting unit 3 through the PID control on the basis of the inputs from the subtractors 74.

As illustrated in FIG. 16, in the comparative example employing the aforementioned configuration, for example, when the main temperature sensor 41m is switched to the secondary temperature sensor 41s by the selection and switching unit 172, a so-called switching shock occurs. Specifically, the manipulated variable MV1 (which is indicated by the dotted line in FIG. 16) of the thermoelectric element 321 increases almost vertically at the sensor switching time point and decreases quickly to equal to or lower than the manipulated variable MV at a time point before the sensor switching time point when the manipulated variable MV1 reaches a peak value (for example, equal to or greater than two times MV1) higher than the peak of the manipulated variable MV1, and the manipulated variable becomes the constant manipulated variable MV1 at a time point before the sensor switching time point. When the thermoelectric element 321 is controlled using the manipulated variable MV according to the comparative example, the detected temperature (which is indicated by the alternated long and short dash line in FIG. 16) of the secondary temperature sensor 41s increases quickly at the sensor switching time point, exceeds (overshoots) the target temperature SV, and then is adjusted to the target temperature SV.

### Operations and Advantages

As described above, the temperature control device 1 for a wafer according to the second embodiment includes the mounting unit 2 including the mounting surface 10 on which a wafer W is mountable, the temperature adjusting unit 3 configured to heat and cool the mounting unit 2, a plurality of temperature sensors 40 provided in the mounting unit 2, and the control device 5 configured to control the temperature adjusting unit 3. The control device 5 includes a plurality of manipulated variable change calculating units 71 provided for the plurality of temperature sensors 40 and configured to calculate a manipulated variable change ΔMV(k) of the temperature adjusting unit 3 on the basis of the detected temperature of the corresponding temperature sensor 40 and the target temperature SV, the selection and switching unit 72 configured to switch a state in which the manipulated variable change ΔMV(k) calculated by one manipulated variable change calculating unit 71 has been selected to a state in which the manipulated variable change ΔMV(k) calculated by the other manipulated variable change calculating unit 71 has been selected, and the manipulated variable calculating unit 73 configured to calculate a manipulated variable MV(k) of the temperature adjusting unit 3 on the basis of the manipulated variable change ΔMV(k) selected by the selection and switching unit 72.

With this configuration, when the state in which the manipulated variable change ΔMV(k) calculated by one manipulated variable change calculating unit 71 has been selected is switched to the state in which the manipulated variable change ΔMV(k) calculated by another manipulated variable change calculating unit 71 has been selected, it is possible to decrease a change of the manipulated variable MV(k) at the time of switching in comparison with a case in which the manipulated variable MV(k) is switched. Accordingly, without extending the time until the temperature of the wafer W is adjusted to the target temperature SV, it is possible to curb overshooting of the wafer temperature with respect to the target temperature SV.

In the second embodiment, the plurality of temperature sensors 40 include the main temperature sensors 41m to 44m and the secondary temperature sensors 41s and 44s, and the plurality of manipulated variable change calculating units 71 include the main manipulated variable change calculating units 711m to 714m configured to calculate the manipulated variable change ΔMV(k) of the temperature adjusting unit 3 on the basis of the detected temperatures of the main temperature sensors 41m to 44m and the target temperature SV and the secondary manipulated variable change calculating units 711s to 714s configured to calculate the manipulated variable change ΔMV(k) of the temperature adjusting unit 3 on the basis of the detected temperatures of the secondary temperature sensors 41s to 44s and the target temperature SV. The selection and switching unit 72 selects one of the manipulated variable change ΔMV(k) calculated by the main manipulated variable change calculating units 711m to 714m and the manipulated variable change ΔMV(k) calculated by the secondary manipulated variable change calculating units 711s to 714s.

Accordingly, when temperature control based on the main temperature sensor and temperature control based on the secondary temperature sensor are switched to each other, a change of a manipulated variable MV(k) can be decreased, and thus it is possible to curb overshooting of the wafer temperature with respect to the target temperature SV.

In the second embodiment, the mounting surface 10 is partitioned into a plurality of areas 21 to 24 in a plan view, and the thermoelectric elements 30 of the temperature adjusting unit 3, the main temperature sensors 41m to 44m, and the secondary temperature sensors 41s to 44s are provided in the corresponding areas 21 to 24. The manipulated variable calculating unit 73 is provided for each of a plurality of thermoelectric elements 321 to 324 of the temperature adjusting unit 3, the main manipulated variable change calculating units 711m to 714m are provided for the corresponding main temperature sensors 41m to 44m, and the secondary manipulated variable change calculating units 711s to 714s are provided for the corresponding secondary temperature sensors 41s to 44s. The selection and switching unit 72 selects one of the manipulated variable change ΔMV(k) calculated by the main manipulated variable change calculating units 711m to 714m and the manipulated variable change ΔMV(k) calculated by the secondary manipulated variable change calculating units 711s to 714s and outputs the selected one to the manipulated variable calculating units 731 to 734 for each of the plurality of areas 21 to 24.

With this configuration, since it is not necessary to provide the same number of manipulated variable calculating units 731 to 734 as the number of temperature sensors 40 or the number of manipulated variable change calculating units 71, it is possible to simplify the circuit configuration of the control device 5.

In the second embodiment, the control device 5 performs the velocity-type PID control using the manipulated variable change calculating units 71 and the manipulated variable calculating units 73.

Accordingly, it is possible to quickly adjust the temperature of the wafer W to the target temperature SV while decreasing the difference between the temperature of the wafer W and the target temperature SV.

The temperature control method for a wafer according to the second embodiment includes: the temperature monitoring step S01 of detecting wafer temperatures at a plurality of positions; the manipulated variable change calculating step S14 of calculating the manipulated variable change ΔMV(k) at each position on the basis of the wafer temperatures at the plurality of positions detected in the temperature monitoring step S01 and a target temperature SV; the selection and switching step S15 of switching a state in which the manipulated variable change ΔMV(k) at one position out of the manipulated variable changes ΔMV(k) at the positions calculated in the manipulated variable change calculating step S14 is selected to a state in which the manipulated variable change ΔMV(k) at another position is selected; the manipulated variable calculating step S16 of calculating an manipulated variable MV(k) by which a temperature is adjusted on the basis of the manipulated variable change ΔMV(k) selected in the selection and switching step S15; and the temperature adjusting step S17 of adjusting the temperature of the wafer W on the basis of the manipulated variable MV(k) calculated in the manipulated variable calculating step S16.

With this configuration, it is possible to decrease a change of the manipulated variable MV(k) at the time of switching in comparison with a case in which the manipulated variable MV(k) is switched. Accordingly, without extending the time until the temperature of the wafer W is adjusted to the target temperature SV, it is possible to curb overshooting of the wafer temperature with respect to the target temperature SV.

### Modified Examples of Second Embodiment

In the second embodiment, an example in which the mounting surface is formed in a circular shape in a plan view has been described above, but the present disclosure is not limited thereto. For example, the mounting surface may be formed in a rectangular shape in a plan view. For example, the shape of the mounting surface in a plan view may be changed according to required specifications such as the shape of the wafer W.

In the second embodiment, an example in which a plurality of temperature sensors 40 are arranged separately from each other in the circumferential direction and the radial direction of the mounting surface in a plan view has been described above, but the present disclosure is not limited thereto. For example, the plurality of temperature sensors 40 may not be arranged separately from each other in the circumferential direction and the radial direction of the mounting surface in a plan view. For example, the arrangement form of the plurality of temperature sensors 40 may be changed according to required specifications.

In the second embodiment, an example in which four areas 21 to 24 with a fan shape are arranged in the circumferential directions has been described above, but the present disclosure is not limited thereto. For example, the shape and the arrangement form of the areas may be changed according to required specifications.

In the second embodiment, an example in which a plurality of sensors 40 are provided in each of the plurality of areas 21 to 24 has been described above, but the present disclosure is not limited thereto. For example, the installation number and the installation positions of the temperature sensors 40 may be changed according to required specifications.

In the second embodiment, an example in which the control device 5 monitors the detected temperatures of the plurality of temperature sensors 40 provided in a predetermined area and selects the detected temperature with a largest change in temperature per unit time out of the plurality of monitored detected temperatures has been described above, but the present disclosure is not limited thereto.

In the second embodiment, an example in which the mounting unit 2 is formed in a plate shape including the mounting surface 10 as the first surface 11 has been described above, but the present disclosure is not limited thereto. For example, the mounting unit 2 may be formed in a block shape including the mounting surface 10 as the first surface 11. For example, the shape of the mounting unit 2 may be changed according to required specifications.

In the second embodiment, an example in which the temperature adjusting unit 3 is provided on the second surface 12 opposite to the surface of the mounting unit 2 on which the mounting surface 10 is provided has been described above, but the present invention is not limited thereto. For example, the temperature adjusting unit 3 may be incorporated into the mounting unit 2. For example, the installation form of the temperature adjusting unit 3 may be changed according to required specifications.

In the second embodiment, an example in which the temperature sensors 40 are disposed in the recessed portions 13 of the mounting unit 2 via the through-holes 31 of the temperature adjusting unit 3 and detect the temperatures of the corresponding areas via the recessed portions 13 of the mounting unit 2 has been described above, but the present disclosure is not limited thereto. For example, the temperature sensors 40 may detect the temperatures of the corresponding areas without using the recessed portions 13 of the mounting unit 2. For example, each temperature sensor 40 may be a non-contact temperature sensor. For example, the form of the temperature sensors 40 may be changed according to required specifications.

In the second embodiment, the temperature control device 1 for controlling the temperature of the wafer W (the temperature of the wafer W to which heat is locally input with supply of electric power) including a chip of which electrical characteristics are inspected with supply of electric power in a target temperature SV has been described as an example of the temperature control device for a wafer, but the present disclosure is not limited thereto. For example, the temperature control device 1 may be applied to a temperature control device for controlling the temperature of the wafer W not including a chip of which electrical characteristics are inspected with supply of electric power in a target temperature SV. For example, the temperature control device 1 may be applied to a temperature control device for controlling the temperature of the wafer W such as a silicon wafer in a target temperature SV. For example, the temperature control device 1 may be used in a dry process. For example, the use form of the temperature control device may be changed according to required specifications.

In the second embodiment, the velocity-type PID control is performed, but the present disclosure is not limited thereto. For example, PD control may be performed instead of the PID control.

While the second embodiment of the present disclosure has been described above, the present disclosure is not limited to the second embodiment, addition, omission, substitution, and other modification of constituents can be performed thereon without departing from the gist of the present disclosure, and the second embodiment can also be appropriately combined.

According to the present disclosure, it is possible to more rapidly adjust the wafer temperature to a target temperature after application of local heat disturbance has stopped. It is also possible to curb occurrence of overshooting.

### EXPLANATION OF REFERENCES

1 Temperature control device
2 Mounting unit
3 Temperature adjusting unit
4 Temperature detecting unit
5 Control device
10 Mounting surface
11 First surface
12 Second surface
13 Recessed portion
21 to 24 Area
30 Thermoelectric element
31 Through-hole
35 Cooling unit
36 Coolant passage
37 Penetrating hole
40 Temperature sensor
41m to 44m Main temperature sensor
41s to 44s Secondary temperature sensor
51 Manipulated variable change calculating unit
52 Selection and switching unit
53 Manipulated variable calculating unit
54 Subtractor
71 Manipulated variable change calculating unit
72 Selection and switching unit
73 Manipulated variable calculating unit
74 Subtractor
105 Control device
152 Selection and switching unit
153 to 156 Manipulated variable calculating unit
172 Selection and switching unit
173 to 176 Manipulated variable calculating unit
321 to 324 Thermoelectric element
511m to 514m Main manipulated variable change calculating unit
511s to 514s Secondary manipulated variable change calculating unit
531 to 534 Manipulated variable calculating unit
711m to 714m Main manipulated variable change calculating unit
711s to 714s Secondary manipulated variable change calculating unit
731 to 734 Manipulated variable calculating unit
S01 Temperature monitoring step
S02 Wafer mounting step
S03 Wafer inspecting step
S04 Manipulated variable change calculating step
S05 Selection and switching step
S06 Manipulated variable calculating step
S07 Temperature adjusting step
S14 Manipulated variable change calculating step
S15 Selection and switching step
S16 Manipulated variable calculating step
S17 Temperature adjusting step
SV Target temperature
W Wafer

1. A temperature control device for a wafer, comprising:
a mounting unit including a mounting surface on which a wafer is mountable and which is partitioned into a plurality of areas in a plan view;
a temperature adjusting unit configured to independently adjust temperatures of the plurality of areas;
a plurality of temperature sensors provided in each of the plurality of areas and configured to detect the temperature of the corresponding area;
a temperature control unit configured to independently control the temperatures of the plurality of areas using the temperature adjusting unit;
a disturbance detecting unit configured to detect application of disturbance to the corresponding area on the basis of a detected temperature from the corresponding temperature sensor; and
a switching unit configured to feed only the detected temperature of the temperature sensor provided in the area to which application of disturbance has been detected back to the temperature control unit when application of disturbance has been detected by the disturbance detecting unit,
wherein the temperature adjusting unit adjusts the temperatures of the plurality of areas on the basis of the detected temperature fed back by the switching unit.

2. The temperature control device for a wafer according to claim 1, wherein the switching unit feeds the detected temperature from the temperature sensor provided in each of the plurality of areas back to the temperature control unit for controlling the temperature adjusting unit of the area provided with the corresponding temperature sensor when application of disturbance to any of the plurality of areas has not been detected.

3. The temperature control device for a wafer according to claim 1, wherein a plurality of the temperature sensors are provided in each of the plurality of areas, and
wherein the temperature control device further comprises a detected temperature selecting unit configured to select a detected temperature with a larger change in temperature per unit time out of the detected temperatures from the plurality of temperature sensors.

4. A temperature control method for the temperature control device for a wafer of claim 1, comprising:
a disturbance detecting step of detecting application of disturbance to a wafer in which a plurality of areas are set in a plan view; and
a disturbance-curbed operation step of independently controlling temperatures of all the areas on the basis of a detected temperature of one area to which application of disturbance has been detected in a feedback manner when application of disturbance has been detected.

5. The temperature control method for the temperature control device for a wafer according to claim 4, further comprising a normal operation step of independently controlling temperatures of the plurality of areas on the basis of the detected temperatures of the areas in a feedback manner when application of disturbance to any area of the wafer has not been detected.

6. A temperature control device for a wafer, comprising:
a mounting unit including a mounting surface on which a wafer is mounted;
a temperature adjusting unit configured to heat or cool the mounting unit;
a plurality of temperature sensors provided in the mounting unit; and
a temperature control device configured to control the temperature adjusting unit,
wherein the temperature control device includes
a plurality of manipulated variable change calculating units provided for each of the plurality of temperature sensors and configured to calculate a manipulated variable change of the temperature adjusting unit on the basis of a detected temperature of the corresponding temperature and a target temperature,
a selection and switching unit configured to switch a state in which the manipulated variable change calculated by one of the plurality of manipulated variable change calculating units is selected to a state in which the manipulated variable change calculated by another of the plurality of manipulated variable change calculating units is selected, and
a manipulated variable calculating unit configured to calculate an amount of operation of the temperature adjusting unit on the basis of the manipulated variable change selected by the selection and switching unit.

7. The temperature control device for a wafer according to claim 6, wherein the plurality of temperature sensors include a main temperature sensor and a secondary temperature sensor,
wherein the plurality of manipulated variable change calculating units include
a main manipulated variable change calculating unit configured to calculate the manipulated variable change of the temperature adjusting unit on the basis of the detected temperature from the main temperature sensor and a target temperature, and
a secondary manipulated variable change calculating unit configured to calculate the manipulated variable change of the temperature adjusting unit on the basis of the detected temperature from the secondary temperature sensor and the target temperature, and
wherein the selection and switching unit selects one of the manipulated variable change calculated by the main manipulated variable change calculating unit and the manipulated variable change calculated by the secondary manipulated variable change calculating unit.

8. The temperature control device for a wafer according to claim 7, wherein the mounting surface is partitioned into a plurality of areas in a plan view,
wherein the temperature adjusting unit, the main temperature sensor, and the secondary temperature sensor are provided in each of the areas,
wherein the manipulated variable calculating unit is provided in each of the plurality of temperature adjusting units,
wherein the main manipulated variable change calculating unit is provided in each of the plurality of main temperature sensors,
wherein the secondary manipulated variable calculating unit is provided in each of the plurality of secondary temperature sensors, and
wherein the selection and switching unit selects one of the manipulated variable change calculated by the main manipulated variable change calculating unit and the manipulated variable change calculated by the secondary manipulated variable change calculating unit and outputs the selected one to the manipulated variable calculating unit for each of the plurality of areas.

9. The temperature control device for a wafer according to claim 6, wherein the temperature control device performs velocity-type PID control using the manipulated variable change calculating unit and the manipulated variable calculating unit.

10. A temperature control method for a wafer, comprising:
a temperature monitoring step of detecting wafer temperatures at a plurality of positions;
a manipulated variable change calculating step of calculating the manipulated variable change at each position on the basis of the wafer temperatures at the plurality of positions detected in the temperature monitoring step and a target temperature;
a selection and switching step of switching a state in which the manipulated variable change at one position out of the manipulated variable changes at the positions calculated in the manipulated variable change calculating step is selected to a state in which the manipulated variable change at another position is selected;
a manipulated variable calculating step of calculating a manipulated variable by which a temperature is adjusted on the basis of the manipulated variable change selected in the selection and switching step; and
a temperature adjusting step of adjusting the wafer temperatures on the basis of the manipulated variable calculated in the manipulated variable calculating step.
